(19) United States
(12) Patent Application Publication
(10) Pub. No.: US 2006/0212766 A1
(43) Pub. Date: Sep. 21, 2006

(54) Display device and driving method thereof

(75) Inventors: Chun-Seok Ko, Gyeonggi-do (KR); Jong-Moo Huh, Gyeonggi-do (KR); Nam-Deog Kim, Gyeonggi-do (KR)

Correspondence Address: David W. Heid;MacPHERSON KWOK CHEN & HEID LLP, Suite 226, 1762 Technology Drive, San Jose, CA, 95110, US

(73) Assignee: Samsung Electronics Co., Ltd.

(21) Appl. No.: 11/367,977

(22) Filed: Mar. 2, 2006

(30) Foreign Application Priority Data
Mar. 4, 2005 (KR) 10-2005-0018115

(51) Int. Cl. G01R 31/28

(52) U.S. Cl. 714/724

(57) ABSTRACT

A display device includes an insulating substrate, a plurality of gate lines formed on the insulating substrate, a plurality of data lines across the gate lines, a plurality of pixels connected to the gate lines and the data lines, a data driver providing data voltages to the pixels, a first switch assembly between the data driver and the data lines to carry the data voltages to the data lines in response to a first selection signal, and a second switch assembly to carry a reverse voltage to the data lines in response to a second selection signal.

### CROSS-REFERENCE TO RELATED APPLICATION

This application claims priority from Korean Patent Application No. 2005-0018115 filed on Mar. 4, 2005, the disclosure of which is hereby incorporated herein by reference in its entirety for all purposes.

### BACKGROUND

1. Field of the Invention

The present invention relates generally to a display device, a driving method thereof, and in particular to an organic light emitting display (OLED) device and a driving method thereof.

2. Description of Related Art

Many consumers want electronic devices with displays to be light and thin. Example of such electronic devices includes mobile communication systems, digital cameras, notebook PCs, monitors, and televisions. One method of reducing display size and weight is to use flat panel displays, such as organic light emitting displays (OLED).

One type of active matrix flat panel display is an active matrix flat panel display. An active matrix flat panel display generally includes a plurality of pixels arranged in a matrix and displays images by controlling the luminance of the pixels based on luminance information indicative of a desired image.

An OLED is self-emissive. OLEDs have desirable characteristics such as a relatively wide viewing angle and a relatively high contrast ratio when compared to liquid crystal displays (LCDs). Further, because an OLED does not require a backlight assembly, OLEDs are lighter and consume less power than LCDs. Other advantageous features include a fast response time, a wide range of operating temperatures, and low manufacturing cost.

A pixel of an OLED includes a light emitting element and a driving transistor. The light emitting element emits light having an intensity value that is dependent on the current driven by the driving transistor, which in turn depends on the threshold voltage of the driving transistor and the voltage between gate and source of the driving transistor.

The transistor includes polysilicon or amorphous silicon as a semiconductor layer. A polysilicon transistor has several advantages, but it also has disadvantages such as the complexity of manufacturing polysilicon, thereby increasing the manufacturing cost. In addition, it is difficult to make a large OLED employing polysilicon transistors.

On the contrary, an amorphous silicon transistor is easily applicable to a large OLED, and is manufactured using a smaller number of process steps than a polysilicon transistor. However, the threshold voltage (Vth) of the amorphous silicon transistor shifts over time, so that the current flowing in the light emitting element is non-uniform. This may degrade image quality.

Thus, there is a need for reducing the threshold voltage shift of the driving transistor.

### SUMMARY OF THE INVENTION

Embodiments of the present invention provide a display device capable of reducing the threshold voltage shift of the driving transistor and a driving method thereof to reduce image degradation.

In an exemplary display panel according to some embodiments of the present invention, the display device includes an insulating substrate, a plurality of gate lines formed over the insulating substrate, a plurality of data lines across the gate lines formed over the insulating substrate, a plurality of pixels including light emitting elements connected the gate lines and the data lines, a first switch assembly configured to transmit data voltages to the data lines in response to a first selection signal, and a second switch assembly configured to transmit a reverse voltage to the data lines in response to a second selection signal.

The data voltages may have a first polarity, and the reverse voltage may have a second opposite polarity. In an embodiment, the absolute value of the reverse voltage is greater than the maximum of the data voltages or about equal to the average of the data voltages.

The first and the second selection signal may be reciprocal.

The display device further comprises a data driver configured to provide the data voltages to the pixels.

The first switch assembly includes a plurality of first switching transistors between the data lines and the data driver. The second switch assembly includes a plurality of second switching transistors between the data lines and the reverse voltage supply.

The first and the second switching transistors are integrated over the insulating substrate and at the end of the data lines.

Each pixel includes a switching transistor connected to an associated gate line and an associated data line, a driving transistor connected to the switching transistor, the light emitting element and a power supply voltage (via a connector), and a capacitor between the driving transistor and the power supply voltage.

The switching transistor and the driving transistor may comprise an n type amorphous semiconductor material.

The display device further comprises a selection signal generator configured to generate the first and the second selection signals. The selection signal generator may be integrated on the insulating substrate.

The display device further comprises a gate driver configured to provide gate signals, and a signal controller configured to control the data driver and the selection signal generator.

The display device may be configured to display an image corresponding to a first set of data voltages during a frame, wherein the frame is divided into a first period for transmitting the first set of data voltages to the data lines, and into a second period for transmitting the reverse voltage to the data lines.

In an exemplary method of driving a display device having a plurality of gate lines, a plurality of data lines across the gate lines, a plurality of pixels connected to the gate lines and the data lines, and a data driver providing data voltages to the pixels includes connecting the data lines to the data driver, applying gate signals to the gate lines, supplying a reverse voltage to the data lines, and applying the gate signals to the gate lines.

The connecting the data lines to the data driver includes disconnecting the reverse voltage from the data lines.

The supplying the reverse voltage to the data lines includes disconnecting the data voltages from the data lines.

The applying the gate signals to the gate lines includes applying the data voltages to the data lines.

### BRIEF DESCRIPTION OF THE DRAWINGS

The features of the present invention will become more apparent to those of ordinary skill in the art in light of the below described exemplary embodiments thereof with reference to the attached drawings, in which:

FIG. 1 is a block diagram of an OLED according to an embodiment of the present invention;

FIG. 2 is an equivalent circuit diagram of a pixel of the OLED of FIG. 1;

FIG. 3 is a cross-sectional view of a driving transistor and a light emitting element of a pixel of an OLED according to an embodiment of the present invention;

FIG. 4 is a schematic view illustrating a multi layered structure of a light emitting member of FIG. 3; and

FIG. 5 is a timing diagram illustrating several signals for operating an OLED such as the OLED of FIG. 1 according to an embodiment of the present invention.

Use of the same reference symbols in different figures indicates similar or identical items.

In the drawings, the thickness of layers and regions are exaggerated for clarity. Like numerals refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

### DETAILED DESCRIPTION OF PREFERRED EMBODIMENTS

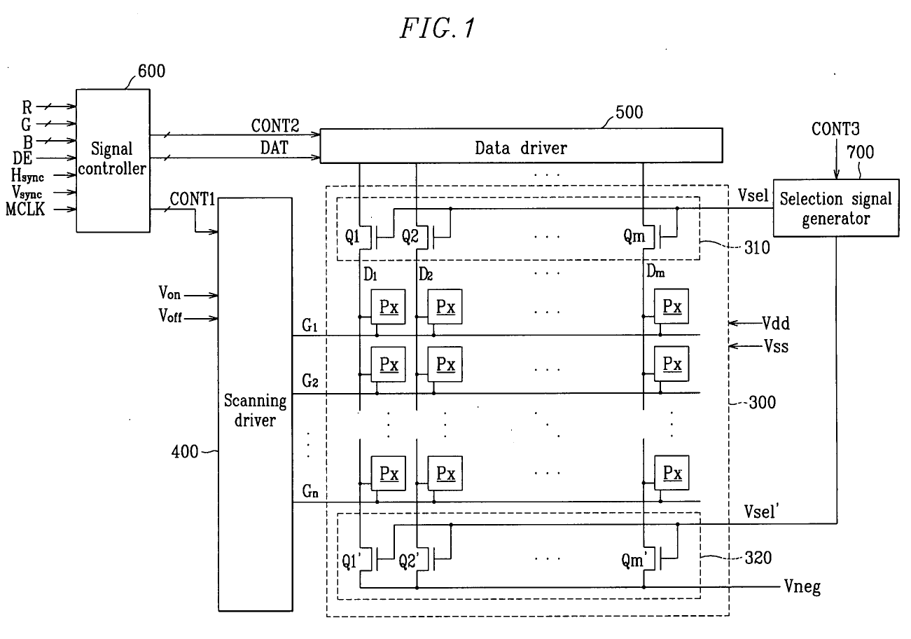

FIG. 1 is a block diagram of an OLED according to an embodiment of the present invention.

Referring to FIG.1, an OLED includes a display panel 300, as well as a scanning (i.e. gate) driver 400, a data driver 500, a selection signal generator 700, and a signal controller 600 connected to the display panel 300.

Display panel 300 includes gate lines G₁-Gₙ, data lines D₁-Dₘ, power supply lines (not shown), a plurality of pixels Px, a first switch assembly 310, and a second switch assembly 320.

Gate lines G₁-Gₙ carry gate signals and extend substantially parallel to one another, in a horizontal direction (in the example shown in FIG. 1). Data lines D₁-Dₘ carry data signals and extend substantially parallel to one another in a vertical direction. Power supply lines (not shown) carry power supplying voltages and may extend in a horizontal or a vertical direction.

In the embodiment illustrated in FIG. 1, pixels are arranged in a matrix configuration and are connected to gate lines G₁-Gₙ, data lines D₁-Dₘ, and power supply lines.

First and second switch assemblies 310 and 320 are located in the end areas of the data lines and include first switching transistors Q₁-Qₘ and second switching transistors Q₁′-Qₘ′ respectively. First switch assembly 310 is connected to data lines D₁-Dₘ and data driver 500. First switch assembly 310 carries data signals from data driver 500 to data lines D₁-Dₘ in response to a first selection signal Vₛₑₗ provided by selection signal generator 700. Second switch assembly 320 connects a reverse voltage V_{neg} to data lines D₁-Dₘ in response to a second selection signal Vₛₑₗ′ provided by selection signal generator 700.

Scanning driver 400 provides gate signals Vg1-Vgm, where the gate signals are either Voff (a voltage sufficient to turn off the associated transistor) or Von (a voltage sufficient to turn on the associated transistor).

Data driver 500 provides data voltages V_{dat} (or signals) to data lines D₁-Dₘ corresponding to image signals.

Selection signal generator 700 provides first selection signal Vₛₑₗ and second selection signal V_{sel′} to control first switching transistors Q₁-Qₘ and second switching transistors Q_{1′}-Q_{m′} respectively. First selection signal Vₛₑₗ and second selection signal V_{sel′} are reciprocal.

In another embodiment, selection signal generator 700 can generate only one of first and second selection signals Vₛₑₗ and V_{sel′}, while a reciprocal signal is generated using an inverter (not shown) integrated on the display panel 300.

In some embodiments, scanning driver 400 and/or data driver 500 are included in chips mounted directly on display panel 300, or on flexible printed circuit films. In some embodiments, scanning driver 400 and/or data driver 500 can be integrated on display panel 300.

Signal controller 600 controls scanning driver 400, data driver 500, and selection signal generator 700.

Image signals (e.g., R, G, and B signals), and input control signals, such as a vertical synchronization signal V_{sync} to activate a frame, a horizontal synchronization signal H_{sync} to activate a line, and a main clock MCLK from an external graphic controller (not shown), are provided to signal controller 600. Signal controller 600 generates scanning control signals CONT1, data control signals CONT2, and selection control signal CONT3 by processing input control signals. Signal controller 600 also converts image signals R, G, and B to image data DAT suitable for display panel 300.

Scanning control signals CONT1 include a scanning start signal STV to initiate scanning and at least one clock signal for controlling the output time of the gate-on voltage Von. The scanning control signals CONT1 may include a plurality of output enable signals for defining the duration of the gate-on voltage Von.

The data control signals CONT2 include a horizontal synchronization start signal STH for initiating data transmission for a group of pixels Px, a load signal LOAD instructing data driver 500 to apply the data voltages to the data lines D₁-Dₘ, and a data clock signal HCLK.

Selection control signals CONT3 initiates activation of first selection signal Vsel and second selection signal Vsel′.

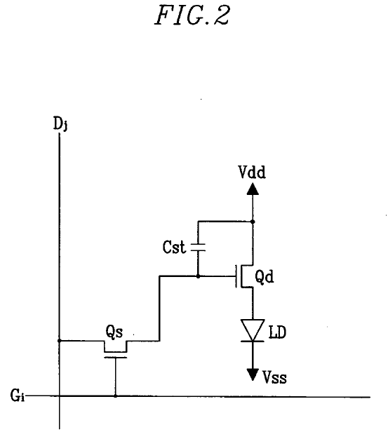

FIG. 2 is a pixel Px of an OLED such as that illustrated in FIG. 1, according to an embodiment of the present invention.

Pixel Px includes a switching transistor Qs, a driving transistor Qd, a capacitor Cst, and a light emitting element LD.

Switching transistor Qs has a control terminal connected to the associated gate line Gᵢ, an input terminal connected to the associated data line Dⱼ, and an output terminal connected to capacitor Cst and driving transistor Qd.

Driving transistor Qd has a control terminal connected to switching transistor Qs and capacitor Cst, an input terminal connected to power supply voltage Vdd, and an output terminal connected to light emitting element LD.

Capacitor Cst is connected between switching transistor Qs and power supply voltage Vdd, and holds a data voltage provided through switching transistor Qs from data line Dj during a desired period.

Light emitting element LD is connected between driving transistor Qd and a common voltage Vss. Light emitting element LD emits light having intensity depending on the output current I_{OLED} of driving transistor Qd. Driving current I_{OLED} depends on the voltage difference Vgs between the control terminal of driving transistor Qd and the output terminal of driving transistor Qd.

In some embodiments, the switching transistors Qs and the driving transistors Qd are n type transistors including amorphous silicon or polysilicon. However, in some embodiments the transistors Qs and Qd may be p type transistors operating in a manner opposite to n type transistor.

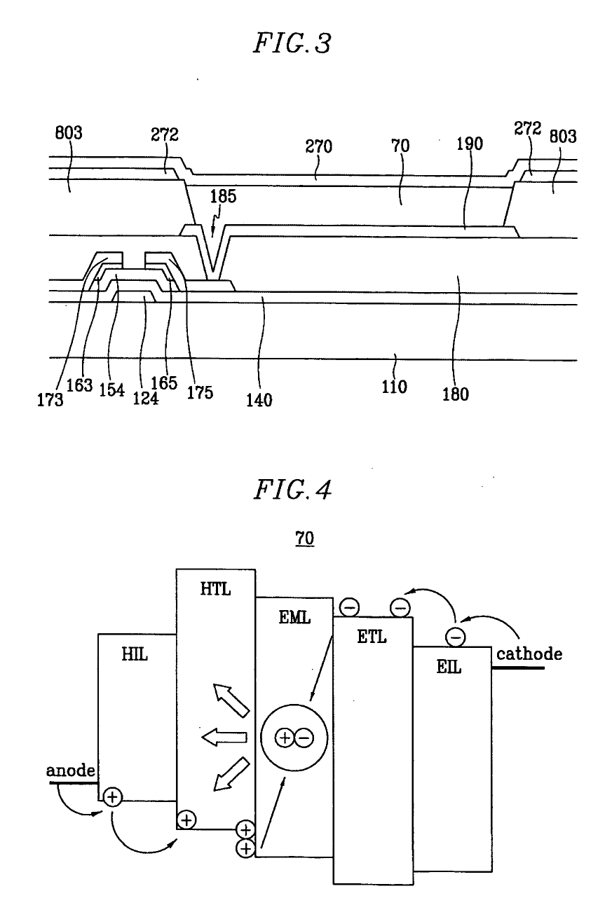

FIG. 3 is a cross sectional view of driving transistor Qd and light emitting element LD of a pixel of an OLED according to an embodiment of the present invention.

A control electrode 124 of driving transistor Qd is formed on an insulating substrate 110. The lateral side of control electrode 124 is inclined at an angle between about 20 and about 80 degrees relative to the surface of insulating substrate 110.

An insulating layer 140 such as a silicon nitride SiNx layer is formed on control electrode 124 and insulating substrate 110.

A semiconductor 154 such as hydrogenated amorphous silicon or polycrystalline silicon is formed on insulating layer 140.

A pair of ohmic contact layers 163 and 165 that may comprise silicide or n+ hydrogenated amorphous silicon doped with n type impurity is formed on semiconductor 154.

The lateral sides of semiconductor 154 and ohmic contact layers 163 and 165 are inclined at an angle of about 30 to about 80 degrees relative to the surface of insulating substrate 110.

An input electrode 173 and an output electrode 175 are formed on ohmic contact layers 163 and 165 and insulating layer 140. Input electrode 173 and output electrode 175 are separated from one another. The lateral sides of input electrode 173 and output electrode 175 are inclined at an angle between about 30 and about 80 degrees.

Driving transistor Qd includes control electrode 124, input electrode 173, and output electrode 175. The channel of driving transistor Qd is formed on semiconductor 154 between input electrode 173 and output electrode 175.

A passivation layer 180 is formed on input electrode 173, output electrode 175, the exposed portion of the semiconductor 154, and the insulating layer 140. In one embodiment, passivation layer 180 comprises an inorganic insulator material such as silicon nitride or silicon oxide, organic material, or a low dielectric constant insulating material that has a dielectric constant lower than 4.0 (such as a-Si:C:O or a-Si:O:F formed by plasma enhanced chemical vapor deposition (PECVD)). In some embodiments, passivation layer 180 can be made of a photosensitive material having sufficient flatness characteristics.

Passivation layer 180 has a contact hole 185 to expose a portion of output electrode 175.

A pixel electrode 190 is formed on passivation layer 180 to connect electrically and physically to output electrode 175 through contact hole 185. Pixel electrode 190 is formed of transparent conductive material such as indium tin oxide (ITO) and/or indium zinc oxide (IZO), or a double layered structure including transparent conductive material and reflective material such as Cr, Al, and/or Ag.

A partition 803 made of organic material and/or inorganic material is formed on passivation layer 180 and has an opening to expose a portion of pixel electrode 190.

An organic light emitting member 70 is formed on the portion of pixel electrode 190 bounded by partition 803.

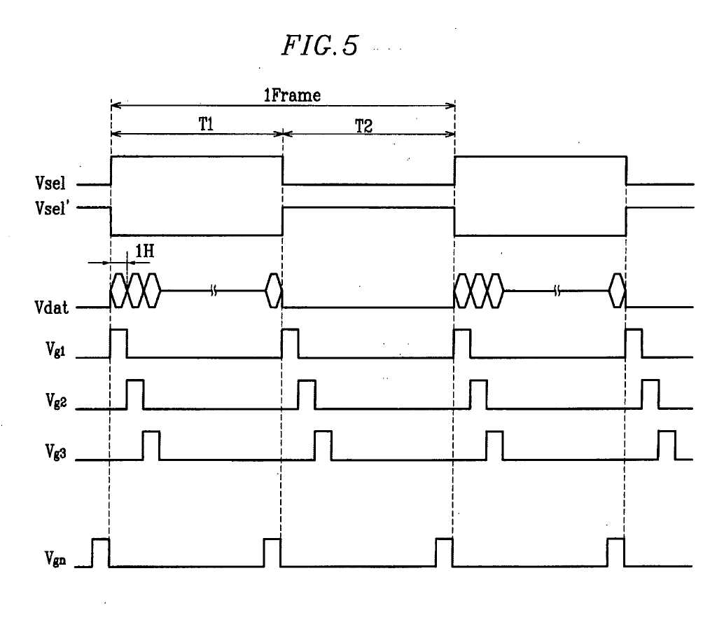

Referring to FIG. 4, organic light emitting member 70 has a multilayered structure including an emitting layer EML and auxiliary layers for improving the efficiency of light emission of the emitting layer EML. The auxiliary layers include an electron transport layer ETL and a hole transport layer HTL for improving the balance of the electrons and holes and an electron injecting layer EIL and a hole injecting layer HIL for improving the injection of the electrons and holes.

An auxiliary electrode 272 comprising a low resistivity material such as Al or an alloy thereof is formed on the partition 803.

A common electrode 270 to be supplied with a common voltage Vss is formed on organic light emitting member 70 and partition 803. When the pixel electrode 190 is transparent, common electrode 270 may comprise metal including Ca, Ba, and/or Al. The common electrode 270 can include transparent conductive material such as ITO and/or IZO.

Auxiliary electrode 272 contacts common electrode 270, and reduces or prevents distortion of the voltage of common electrode 270 by compensating for the lower conductivity of common electrode 270.

A combination of opaque pixel electrodes 190 and a transparent common electrode 270 is employed in a top emission OLED that emits light toward the top of display panel 300. A combination of transparent pixel electrodes 190 and an opaque common electrode 270 is employed in a bottom emission OLED that emits light toward the bottom of the display panel 300.

Pixel electrode 190, organic light emitting member 70, and common electrode 270 form a light emitting element LD having pixel electrode 190 as an anode and common electrode 270 as a cathode or vice versa. Light emitting element LD uniquely emits one of a set of primary color lights, depending on the material of light emitting member 70. An exemplary set of primary colors includes three primary colors: red, green, and blue. The display of images is realized by the addition of the three primary colors.

Pixel Px of embodiments of the present invention has a switching transistor, a driving transistor, a capacitor, and a light emitting element. The described configuration may be used to simplify the pixel and reduce pixel size, thereby achieving a high resolution display.

FIG. 5 is a timing diagram illustrating several signals for operating an OLED such as that illustrated in FIG. 1 according an embodiment of the present invention.

Signal controller 600 of FIG. 1 divides a frame to two periods T₁ and T₂ for displaying images. Data voltages V_{dat} are transmitted to pixels Px during a first period T₁, in response to the application of first selection signal Vₛₑₗ to first switching transistors Q₁-Qₘ. Reverse voltage V_{neg} is transmitted to pixels Px during a second period T₂, in response to the application of second selection signal V_{sel′} to second switching transistors Q₁′-Qₘ′.

Referring to FIGS. 1 and 5, selection signal generator 700 changes first selection voltage Vₛₑₗ to the high voltage and second selection voltage V_{sel′} to the low voltage to start first period T₁ responsive to selection control signal CONT3. In response to high (gate on) first selection voltage Vₛₑₗ, first switching transistors Q₁-Qₘ turn on and data lines D₁-Dₘ are connected to data driver 500. Low (gate off) second selection voltage V_{sel′} separates reverse voltage V_{neg} from data lines D₁-Dₘ.

In response to data control signals CONT2 from the signal controller 600, data driver 500 receives a group of image data DAT, for example, data for the n-th pixel row, from signal controller 600. Data driver 500 converts the image data DAT into analog data voltages V_{dat}. Data signals V_{dat} are applied to data lines D₁-Dₘ.

Scanning driver 400 generates a scanning signal V_{gn} for the n-th gate signal line Gₙ equal to the gate-on voltage Vₒₙ, in response to the scanning control signals CONT1 from signal controller 600, thereby turning on the switching transistors Qs connected to the n-th gate signal line Gₙ. The data voltages V_{dat} applied to the data lines D₁-Dₘ are supplied to the control terminals of driving transistor Qd.

Data voltage V_{dat} supplied to driving transistor Qd charges each capacitor Cst to maintain data voltages V_{dat} for a desired period. Data voltage V_{dat} turns on driving transistors Qd and outputs driving current I_{OLED} which depends on the amount of data voltage V_{dat}. Driving current I_{OLED} flows through light emitting element LD, which emits light having different intensity depending on driving current I_{OLED}.

By repeating this procedure for each gate line during successive units of a horizontal period (which is denoted by “1H” and equal to one period of the horizontal synchronization signal H_{sync}) all gate lines G₁-Gₙ are sequentially supplied with the gate-on voltage Vₒₙ during first period T₁, thereby applying the data voltages to all pixels.

After applying the data voltages to all pixels, selection signal generator 700 changes first selection signal Vₛₑₗ to the low (gate off) voltage and second selection signal V_{sel′} to the high (gate on) voltage in response to selection control signal CONT3 from signal controller 600. In response to high second selection voltage V_{sel′}, second switching transistors Q_{1′}-Q_{m′} turn on to apply reverse voltage V_{neg} to data lines D₁-Dₘ, to start second period T2. Low first selection voltage Vₛₑₗ separates data driver 500 from data lines D₁-Dₘ.

During second period T2, scanning driver 400 makes a scanning signal V_{gn} for the n-th gate signal line Gₙ equal to the gate-on voltage Vₒₙ in response to the scanning control signal CONT1 from signal controller 600, thereby turning on transistors Qs connected to the n-th gate signal line Gₙ. The reverse voltage V_{neg} applied to data lines D₁-Dₘ is supplied to the control terminals of the associated driving transistors Qd.

Reverse voltage V_{neg} supplied to driving transistors Qd charges each capacitor Cst and is maintained for a desired period. Reverse voltage V_{neg} has an opposite polarity to data voltage V_{dat}. For example, if data voltage V_{dat} has positive polarity, the reverse voltage V_{neg} has negative polarity. The level of reverse voltage V_{neg} depends on various factors, such as the level of data voltage V_{dat}, and the type and characteristics of light emitting element LD. In one embodiment, the absolute value of reverse voltage V_{neg} is higher than the maximum absolute value of data voltages V_{dat} or is approximately equal to the average absolute value of data voltages V_{dat}.

Reverse voltage V_{neg} turns off driving transistors Qd, so the associated light emitting elements LD do not emit light.

By repeating this procedure for each gate line during successive horizontal time periods 1H, all gate lines G₁-Gₙ are sequentially supplied with the gate-on voltage Vₒₙ during second period T₂, thereby applying reverse voltage V_{neg} to all pixels.

Reverse voltage V_{neg} releases stress caused by data voltages V_{dat} during first period T₁, and reduces the threshold voltage shift of driving transistor Qd. Accordingly, image degradation caused by the threshold voltage shift is reduced.

After a frame ends, the load of the data voltage V_{dat} for the next frame starts and the same procedures are repeated.

The length of each period T1 and T2 can be adjusted. In one embodiment, the length of each period T₁ and T₂ is the same.

The emissive period of each pixel is delayed by 1H. Thus, the emissive period of first row pixels substantially coincides with first period T₁, but the emissive period of the last row pixels substantially coincides with second period T₂. The non emissive period initiated by reverse voltage V_{neg} is delayed by 1H, like the emissive period. The present disclosure thus provides an impulsive effect by dividing a frame into an emissive period and a non emissive period to reduce image blurring.

According to embodiments of the present invention, the threshold voltage shift of a driving transistor is reduced by applying a reverse voltage to the driving transistor, to decrease image degradation. Also, each pixel has a simple circuit including a switching transistor, a driving transistor, a capacitor and a light emitting element, to reduce a pixel size while achieving a high resolution display.

Although the invention has been described with reference to particular embodiments, the description is an example of the invention's application and should not be taken as a limitation. Various adaptations and combinations of the features of the embodiments disclosed are within the scope of the invention as defined by the following claims.

What is claimed is:

1. A display device comprising:
an insulating substrate
a plurality of gate lines formed over the insulating substrate;
a plurality of data lines across the gate lines;
a plurality of pixels including light emitting elements connected to the gate lines and the data lines;
a first switch assembly configured to transmit data voltages having a first polarity to the data lines in response to a first selection signal; and
a second switch assembly configured to transmit a reverse voltage to the data lines in response to a second selection signal.

2. The display device of claim 1, wherein the reverse voltage has a second polarity opposite the first polarity.

3. The display device of claim 2, wherein the absolute value of the reverse voltage is higher than the maximum absolute value of the data voltages or substantially equal to the average absolute value of the data voltages.

4. The display device of claim 2, further comprising a data driver configured to provide the data voltages to the data lines.

5. The display device of claim 4, wherein the first switch assembly connects the data driver to the data lines to transmit the data voltages:

6. The display device of claim 5, wherein the first switch assembly includes a plurality of first switching transistors between the data drivers and the data lines.

7. The display device of claim 6, wherein the second switch assembly includes a plurality of second switching transistors configured to transmit the reverse voltage to the data lines.

8. The display device of claim 7, wherein the first and the second switch assemblies are formed on the substrate.

9. The display device of claim 7, wherein the first and the second switch assemblies are formed directly on the substrate.

10. The display device of claim 8, wherein the first and the second switch assemblies are integrated at the ends of the data lines.

11. The display device of claim 2, wherein each of the plurality of pixels further comprises:
a switching transistor connected to the data line and the gate line;
a driving transistor connected to the switching transistor, the associated light emitting element and a connector configured to receive a power supply voltage; and
a capacitor connected to the driving transistor and the connector.

12. The display device of claim 11, wherein the switching transistor and the driving transistor comprise an n type amorphous semiconductor material.

13. The display device of claim 2, wherein the first and the second selection signals are reciprocal.

14. The display device of claim 13, further comprising a selection signal generator configured to generate the first and the second selection signals.

15. The display device of claim 14, wherein the selection signal generator is integrated on the insulating substrate.

16. The display device of claim 15, further comprising;
a gate driver configured to supply the gate signals to the gate lines; and
a signal controller configured to control the gate driver, the data driver and the selection signal generator.

17. The display device of claim 2, wherein the display device is configured to display an image corresponding to a first set of data voltages during a frame, wherein the frame is divided into a first period for transmitting the first set of data voltages to the data lines, and into a second period for transmitting the reverse voltage to the data lines.

18. A method for driving a display device having a plurality of gate lines, a plurality of data lines across the gate lines, a plurality of pixels connected to the gate lines and the data lines, and a data driver providing data voltages to the pixels comprising:
connecting the data lines to the data driver;
applying gate signals to the gate lines;
supplying a reverse voltage to the data lines; and
applying the gate signals to the gate lines.

19. A method of claim 18, wherein the data voltages have a first polarity, and wherein the reverse voltage has a second opposite polarity.

20. A method of claim 19, wherein connecting the data lines to the data driver comprises disconnecting the reverse voltage from the data lines.

21. A method of claim 20, wherein supplying the reverse voltage to the data lines comprises disconnecting the data lines from the data driver.

22. A method of claim 21, wherein applying the gate signals to the gate lines comprises applying the data voltages to the data lines.
